(19) United States
(12) Patent Application Publication
(10) Pub. No.: US 2007/0054050 A1
(43) Pub. Date: Mar. 8, 2007

(54) Photoresist coating apparatus and method

(75) Inventors: Jin Sung Lee, Seoul (KR); Jun Mo Koo, Youngin-si (KR); Seong Gu Kim, Pyeontaek-si (KR); Tae Gyu Kim, Hwaseong-si (KR); Tae Sang Park, Suwon-si (KR); Chang Hoon Jung, Seoul (KR); Dong Woo Lee, Seoul (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 11/372,376

(22) Filed: Mar. 10, 2006

(30) Foreign Application Priority Data
Sep. 6, 2005 (KR) 10-2005-0082479

(51) Int. Cl. B05B 5/025; B05C 11/02; C23C 16/00

(52) U.S. Cl. 427/248.1; 118/52; 118/629; 427/240; 427/460

(57) ABSTRACT

A photoresist coating apparatus and method for solving an edge bead problem occurring in photoresist coating. An edge bead is prevented from occurring by forming a solvent vapor layer from ionized solvent vapor on a wafer through the use of a magnetic field generator, spraying a liquid photoresist on the wafer, and controlling the liquid photoresist to not vaporize more at the edge of the wafer than towards the center thereof. A photoresist coating apparatus includes: a solvent ionizer supplying ionized solvent vapor; and a magnetic field generator forming a solvent vapor layer on a wafer from the ionized solvent vapor.

### CROSS-REFERENCE TO RELATED APPLICATION

This application claims the benefit of Korean Patent Application No. 2005-82479, filed on Sep. 6, 2005, in the Korean Intellectual Property Office, the disclosure of which is incorporated herein by reference.

### BACKGROUND OF THE INVENTION

1. Field of the Invention

The present invention relates to a photoresist coating apparatus and method, and more particularly, to a photoresist coating apparatus and method for solving an edge bead problem which occurs in photoresist coating.

2. Description of Related Art

Photoresist coating is a process which is widely used in the manufacture of, for example, semiconductors, LCDs (Liquid Crystal Displays), MEMS (Micro Elector Mechanical Systems). A photoresist is coated on a wafer by evenly placing a liquid photoresist on the wafer and vaporizing the solvent of the liquid photoresist. In the next step, if the photoresist is exposed by using a mask, the exposed photoresist portion is removed and the rest of the photoresist remains.

Photoresist coating methods can be divided into a spin method and a spinless or spray method. Hereinafter, photoresist coating of the spin method and that of the spinless or V spray method will be briefly described.

FIG. 1 is a view illustrating a photoresist coating apparatus of a spin method according to a conventional art.

First, a wafer 102 is placed on a wafer support 103. Later, a liquid photoresist 105 is dropped on the wafer 102 from a photoresist nozzle 101 (hereinafter, PR nozzle). A liquid photoresist is a photoresist that has been dissolved into liquid by a solvent. In the next step, if the wafer 102 revolves by rotating a rotation axle 104, the liquid photoresist 105 dropped on the wafer 102 spreads on the wafer 102. Photoresist coats the wafer 102 by vaporizing the solvent of the liquid photoresist 105. However, in this instance, an edge bead problem may occur at the edge of the wafer 102. As a result, the photoresist leaves a coat on the edge of the wafer 102 that may be thicker than other areas of the wafer and thus may be protruded. The edge bead problem will be described in further detail with reference to FIG. 3 after first describing photoresist coating of a spinless method.

FIG. 2 is a view illustrating a photoresist coating apparatus of a spray method according to the conventional art.

First, a wafer 202 is placed on a wafer support 203 supported by support 204. Later, a liquid photoresist 205 is sprayed on the waver 205 from a photoresist spray nozzle 201 (hereinafter, PR spray nozzle) and the liquid photoresist is spread on the waver 202. In the next step, photoresist coats the wafer 202 by vaporizing the solvent of the liquid photoresist 205.

In the spray method, when a liquid photoresist is sprayed on a wafer, the solvent of the liquid photoresist vaporizes before the liquid photoresist reaches the surface of the wafer, and the photoresist becomes solid particles which drop on the wafer. As noted above, the photoresist drops on the wafer as solid particles, not as a liquid, which causes an uneven coat of the photoresist on the wafer. Accordingly, since an exposure process performed after the spray process is not properly implemented, the yield rate decreases.

Also, a down flow 206 occurs in most semiconductor processes including the photoresist coating process. This is to make impurities generated during the photoresist process drop on the floor, not on the wafer. However, in the spray method, a part of the sprayed liquid photoresist is lost because of the down flow 206. Namely, the liquid photoresist sprayed from the PR spray nozzle 201 rides the down flow 206 and drops not on the wafer, but on the floor. If the liquid photoresist is lost as described above, it causes an increase in the cost of materials for the photoresist coating process.

In particular, in photoresist coating of the spin method as illustrated in FIG. 1, since a photoresist coating apparatus cannot be embodied as an enclosed system, the down flow is always in effect. In the case of the spin method, while a wafer rotates, the liquid photoresist placed on the wafer splatters to the outside off the wafer. On the other hand, if the photoresist coating apparatus is embodied as an enclosed system, the splattered liquid photoresist may splatter against a wall and may bounce back onto the wafer. In this instance, the photoresist is unevenly coated on the wafer. Thus, the spin method is embodied as an open system, and through this, the liquid photoresist splatters to the outside and the down flow forces the liquid photoresist to the floor.

However, in this instance, an edge bead problem may occur at the edge of the wafer 102 and because of the edge bead problem, the photoresist coating on the edge of the wafer 102 may be protruded.

FIG. 3, parts a-c, are views for explaining an edge bead problem according to conventional art.

When either the spin method or the spray method, an even liquid photoresist film 302 is first formed on a wafer 301 and photoresist is coated on the wafer 301 by vaporizing the solvent of the liquid photoresist film 302.

In this instance, since the superficial area of the liquid photoresist film 302 formed on the wafer 301 is larger at the edge of the wafer 301 than towards the center thereof, the solvent of the liquid photoresist film 302 vaporizes more at the edge of the wafer 301. As illustrated in parts (a) and (b) of FIG. 3, at the edge of the wafer 301, both the upper surface and the side surface of the liquid photoresist film 302 makes contact with air, and the vaporization occurs both on the upper surface and the side surface. However, towards the center of the wafer 301, only the upper surface of the liquid photoresist film 302 makes contact with air and the vaporization thereof also occurs only on the upper surface. Accordingly, more solvent vaporizes at the edge 303 of the wafer 301 than towards the center thereof.

As described above, since more solvent vaporizes at the edge of a wafer than towards the center thereof, the density of the liquid photoresist is richer at the edge of the wafer than towards the center thereof. When the density of the liquid photoresist increases, the surface tension also increases. Thus, as show in part (c) of FIG. 3, the edge bead problem occurs in that the edge 304 protrudes after the solvent vaporizes.

A photoresist should be evenly coated on a wafer. However, if the photoresist coated on the wafer is protruded at the edge of the wafer, this part becomes useless and has to be cut off. Accordingly, the edge bead problem decreases the yield of semiconductors.

The edge bead problem as described above may occur not only in the photoresist coating of the spray method but also in the photoresist coating of the spin method. Accordingly, there is needed a photoresist coating apparatus and method which can solve the edge bead problem as above and increase the yield of semiconductors.

### BRIEF SUMMARY

An aspect of the present invention provides a photoresist coating apparatus and method in which a bead is not formed at the edge of a wafer in the photoresist coating and the photoresist is evenly coated on the wafer.

Another aspect of the present invention provides a photoresist coating apparatus and method which can reduce the amount of liquid photoresist lost from riding the down flow and dropping on the floor during the photoresist coating process.

Still another aspect of the present invention reduces the amount of photoresist dropping on a wafer as solid particles as solvent vaporizes, when the photoresist is coated on the wafer in a spray method.

Yet another aspect of the present invention provides a photoresist coating apparatus and method which controls the vaporization of the solvent of a liquid photoresist film at the initial stage of forming the liquid photoresist film on the wafer, and enables the liquid photoresist film to be evenly formed on the wafer.

Another aspect of the present invention provides a photoresist coating apparatus and method which fosters of the vaporization of the solvent of a liquid photoresist film at the later stage of forming the liquid photoresist film on the wafer, and enables the liquid photoresist film to be quickly formed on the wafer and reduces time spent in the photoresist coating process.

Yet another aspect of the present invention provides a photoresist coating apparatus and method which can adjust the vertical and horizontal density of a solvent vapor layer formed on the wafer.

According to an aspect of the present invention, there is provided a photoresist coating apparatus including a solvent ionizer supplying ionized solvent vapor and a magnetic field generator forming a solvent vapor layer of the ionized solvent vapor on the wafer.

The solvent ionizer ionizes solvent vapor by using an ion wind, thereby generating the ionized solvent vapor. The solvent ionizer includes an ion wind generator generating the ion wind and a piezoelectric device vaporizing the solvent, thereby generating the solvent vapor.

The magnetic field generator is disposed around the circumference of the wafer, and serves to form a solvent vapor layer of the ionized solvent vapor on the wafer. Also, the photoresist coating apparatus may include a position controller horizontally moving the magnetic field generator in relation to the wafer.

A coating apparatus according to an aspect of the present invention includes a solvent ionizer supplying ionized solvent vapor and a magnetic field generator forming a solvent vapor layer of the ionized solvent vapor on a wafer.

A photoresist coating method according to another aspect of the present invention includes: forming a solvent vapor layer from ionized solvent vapor on a wafer by using a magnetic field generator; dropping a liquid photoresist on a wafer and rotating the wafer, and vaporizing the solvent of the liquid photoresist. The ionized solvent vapor is generated by using an ion wind to ionize solvent vapor.

The magnetic field generator may be disposed around the circumference of the wafer. The magnetic field generator may control the vertical and horizontal density of the solvent vapor layer formed on the wafer by controlling the strength of the magnetic field in the vertical and horizontal directions.

A photoresist coating method according to still another aspect of the present invention includes: forming a solvent vapor layer by ionized solvent vapor on a wafer by using a magnetic field generator; spraying a liquid photoresist on the wafer; and vaporizing the solvent of the liquid photoresist.

In this instance, the height of a spray nozzle spraying the liquid photoresist on the surface of the wafer may be substantially identical to the height of the solvent vapor layer. Also, the magnetic field generator may be controlled so that the density of the lower portion of a solvent vapor layer formed on the wafer is richer than the density of the upper portion of the solvent vapor layer at the initial stage of spraying the liquid photoresist. Also, the magnetic field generator may be controlled so that the density of the upper portion of a solvent vapor layer formed on the wafer is richer than the density of the lower portion of the solvent vapor layer at the later stage of spaying the liquid photoresist.

Additional and/or other aspects and advantages of the present invention will be set forth in part in the description which follows and, in part, will be obvious from the description, or may be learned by practice of the invention.

### BRIEF DESCRIPTION OF THE DRAWINGS

The above and/or other aspects and advantages of the present invention will become apparent and more readily appreciated from the following detailed description, taken in conjunction with the accompanying drawings of which:

FIG. 1 is a view illustrating a photoresist coating apparatus of a spin method according to a conventional art;

FIG. 2 is a view illustrating a photoresist coating apparatus of a spray method according to the conventional art;

FIG. 3, parts a-c, are views for explaining an edge bead problem according to the conventional art;

FIG. 4 is a view illustrating a photoresist coating apparatus according to an embodiment of the present invention;

FIG. 5 is a view illustrating a photoresist coating apparatus according to an embodiment of the present invention;

FIG. 6 is a view illustrating a solvent ionizer supplying ionized solvent vapor according to an embodiment of the present invention;

FIG. 7, parts a-b, are views for explaining the operations of a magnetic field generator included in the photoresist coating apparatus according to the present invention;

FIG. 8, parts a-c, are views for explaining a configuration of including magnets formed of a plurality of layers in a magnetic field generator and controlling the strength of the magnetic field in the vertical direction in accordance with an embodiment of the present invention;

FIG. 9 is a view for explaining a position controller horizontally moving a magnet included in a magnetic field generator, in order to control the strength of the magnetic field in the horizontal direction in accordance with an embodiment of the present invention;

FIG. 10 is a view for explaining a position controller vertically moving a wafer in accordance with an embodiment of the present invention;

FIGS. 11 and 12 are views explaining a process of coating photoresist in a spray method in accordance with an embodiment of the present invention;

FIG. 13 is a view for explaining how an edge bead problem is solved in accordance with the present invention; and

FIG. 14 is a view explaining a process of coating photoresist in a spin method in accordance with an embodiment of the present invention.

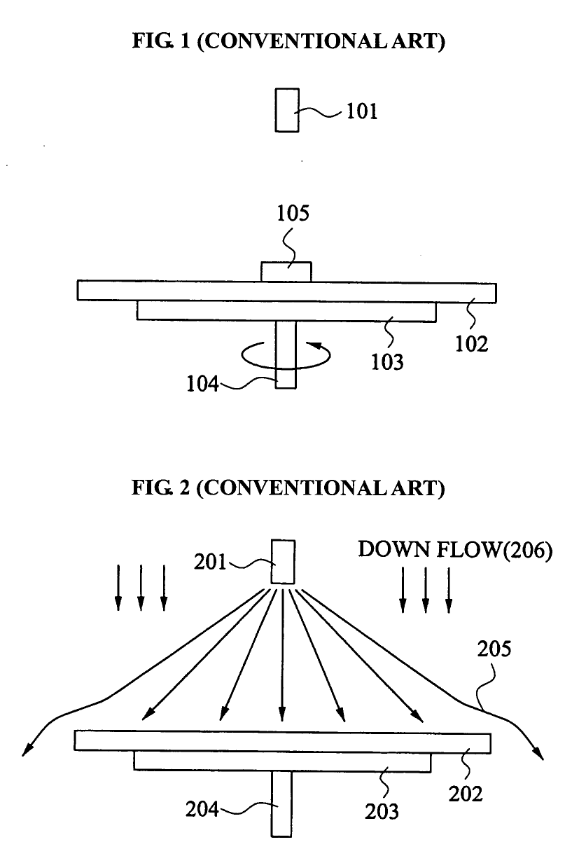

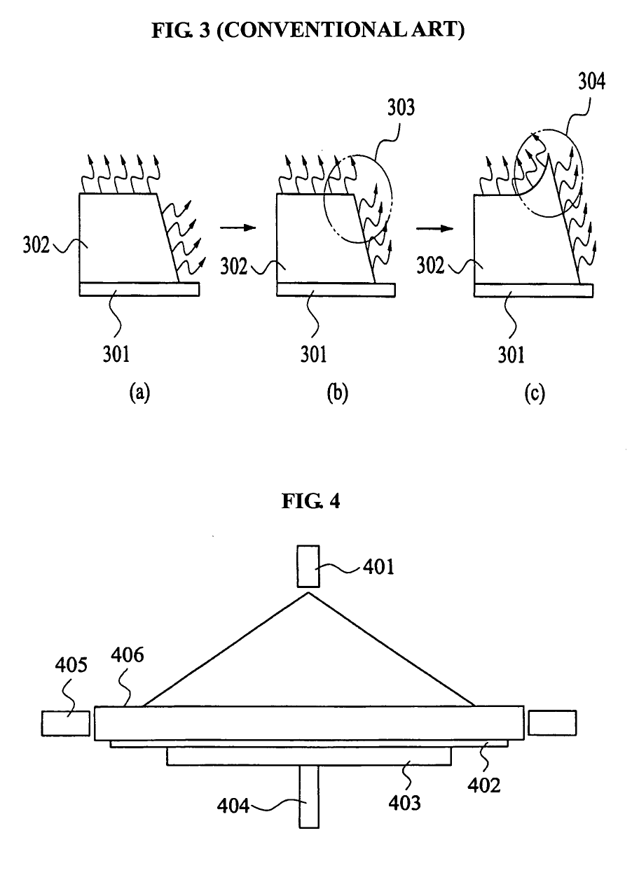

### DETAILED DESCRIPTION OF EMBODIMENTS

Reference will now be made in detail to embodiments of the present invention, examples of which are illustrated in the accompanying drawings, wherein like reference numerals refer to the like elements throughout. The embodiments are described below in order to explain the present invention by referring to the figures.

For convenience of description, while embodiments of the present invention mainly describes a photoresist coating apparatus of a spray method, the present invention is not limited thereto. Also, embodiments of the present invention are applicable not only to the photoresist coating apparatus of the spray method but also to a photoresist coating apparatus of another method, such as a photoresist coating apparatus of a spin method.

FIG. 4 is a view illustrating a photoresist coating apparatus according to an embodiment of the present invention.

A wafer 402 is placed on a wafer support 403. In the present embodiment, an ionized solvent vapor layer 406 is formed on the wafer 402. Also, the ionized solvent vapor layer 406 is maintained on the wafer 402 by a magnetic field generator 405. That is, after the ionized solvent vapor is supplied on the wafer 402, the magnetic field generated by the magnetic field generator 405 prevents a large amount of the ionized solvent vapor from dropping to the floor or being blown away, and maintains large amount of the ionized solvent vapor on the wafer 402. The solvent vapor layer surrounds a liquid photoresist and prevents a liquid photoresist film formed on the wafer from vaporizing. In this manner, an edge bead problem is solved.

Without maintaining solvent vapor on a wafer via a magnetic field generator, photoresist coating can be continued while supplying the solvent vapor. According to the above described embodiment, a liquid photoresist film is protected by a solvent vapor layer, and the edge bead problem can be solved. However, in this case, the solvent vapor has to be continuously supplied and also, more solvent vapor has to be supplied on the edge of the wafer as described later. This drawback is very difficult to overcome. Accordingly, if the solvent vapor is maintained on the wafer by using the magnetic field generator, it is not necessary to continuously supply the solvent vapor.

The magnetic field generator 405 maintains ionized solvent vapor on a wafer. Thus, other apparatuses such as an electric field generator for the same purpose are also included in the magnetic field generator of the present embodiment.

In the spray method, a PR spray nozzle 401 sprays a liquid photoresist on the wafer 402 under the protection of the ionized solvent vapor layer. In the spin method, a liquid photoresist is evenly placed on the wafer 402 by dropping the liquid photoresist on the wafer 402 via the PR spray nozzle 401 and rotating a rotation axle 404.

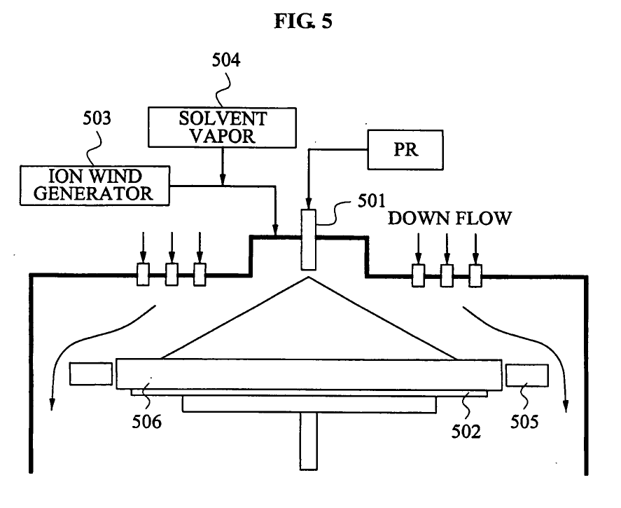

FIG. 5 is a view illustrating further in detail the photoresist coating apparatus according to an embodiment of the present invention.

The photoresist coating apparatus of the present embodiment includes a solvent ionizer (not shown) and a magnetic field generator 505. The solvent ionizer supplies ionized solvent vapor, and a magnetic field generator 505 forms a solvent vapor layer 506 by the ionized solvent vapor on a wafer.

The solvent ionizer ionizes solvent vapor 504 by using an ion wind, thereby generating the ionized solvent vapor. For example, the ionized solvent vapor may be generated by ionizing solvent vapor 504 by using the ion wind which is generated by an ion wind generator 503. The generated ionized solvent vapor is supplied on a wafer 502. In this instance, since the supplied ionized solvent vapor has been ionized, a large amount thereof becomes maintained on the wafer 502 by the magnetic field generator 505. That is, the solvent vapor layer 506 consisting of solvent vapor ionized by the magnetic field generator 505 is formed on the wafer 502.

Next, a liquid photoresist is sprayed on the wafer 502 from a PR spray nozzle 501. Since the liquid photoresist sprayed from the PR spray nozzle 501 immediately enters into the solvent vapor layer 506, the possibility that the sprayed liquid photoresist vaporizes before reaching the surface of the wafer 502 reduces significantly. Thus, according to the present embodiment, it is possible to solve a problem that the solvent of the sprayed liquid photoresist vaporizes before reaching the wafer and the liquid photoresist drops on the wafer in solid particles.

Also, according to the present embodiment, since the ionized solvent vapor layer 506 surrounds the liquid photoresist on the wafer 502, the ionized solvent vapor layer 506 protects the liquid photoresist from the down flow. Thus, the present embodiments prevents the loss of the liquid photoresist caused by the down flow.

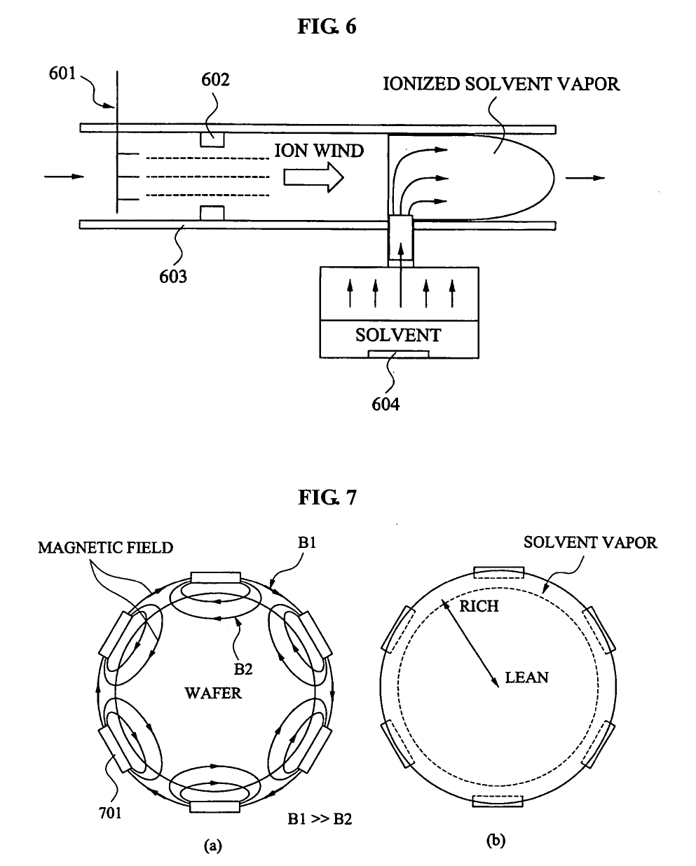

FIG. 6 is a view illustrating a solvent ionizer supplying ionized solvent vapor according to an embodiment of the present invention.

The solvent ionizer includes an ion wind generator (not shown) and a piezoelectric device.

The ion wind generator generates the ion wind, and includes a corona discharger 601, an earthed electrode 602, an insulating conductor 603, and a piezoelectric device 604. The corona discharger 601 generates a corona discharge, thereby generating negative ions. The corona discharge is to gather positive ions in a corona discharging wire of the corona discharger 601 and to discharge negative ions. Negative ions generated by the corona discharge are guided along the insulating conductor 603 to the position where solvent vapor is formed.

A piezoelectric device 604 vaporizes a solvent, thereby generating the solvent vapor. Other devices vaporizing a solvent to generate solvent vapor besides the piezoelectric device 604 may be used.

Solvent vapor generated by the piezoelectric device 604 is combined with ions of the ion wind generated by an ion wind generator to become ionized solvent vapor.

FIG. 7 is a view for explaining the operations of a magnetic field generator included in the photoresist coating apparatus according to the present invention. FIG. 7 is a top plan view of the photoresist coating apparatus of FIG. 5.

In FIG. 7, parts a-b, a magnetic field generator consists of 6 magnets 701 disposed around the circumference of a wafer. The magnets may be permanent magnets or electromagnets. Also, 6 magnets have been used in FIG. 7, but the number of magnets may be appropriate for the use in accordance with each embodiment.

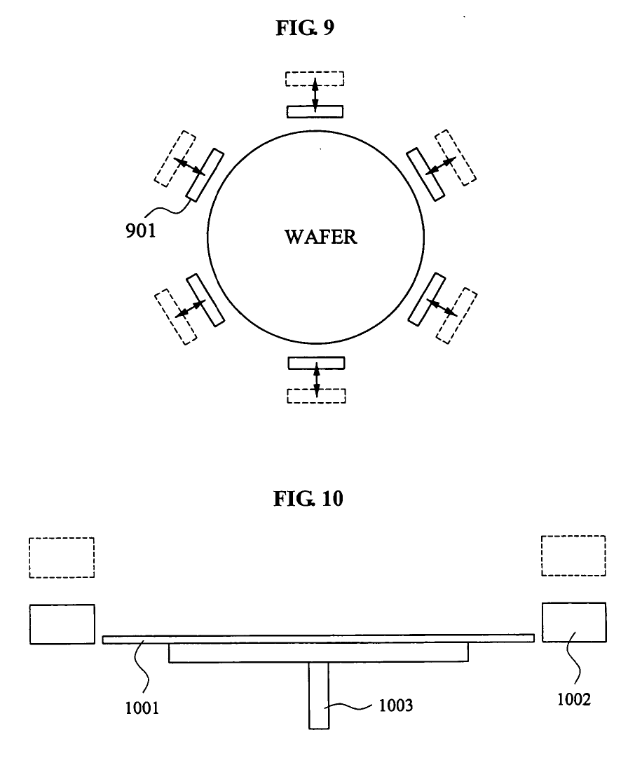

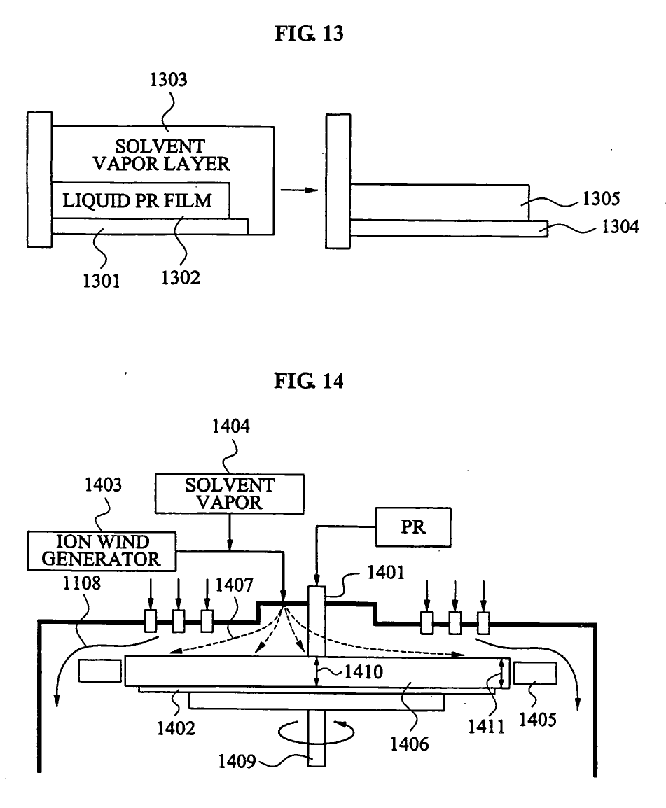

As illustrated in part (a) of FIG. 7, since a magnetic field generator is provided around the circumference of a wafer, the strength of the magnetic field B1 is stronger at the edge of the wafer than the magnetic field B2 towards the center of the wafer. Accordingly, as illustrated in part (b) of FIG. 7, the density of the ionized solvent vapor formed on the wafer is lean towards the center of the wafer and rich at the edge of the wafer. As above, the vertical density of the solvent vapor layer formed on the wafer may be controlled by adjusting the strength of the magnetic field of the magnetic field generator provided around the circumference of the wafer. By using this, an edge bead problem may be solved. Description related thereto will be described later with reference to FIGS. 9 and 13.

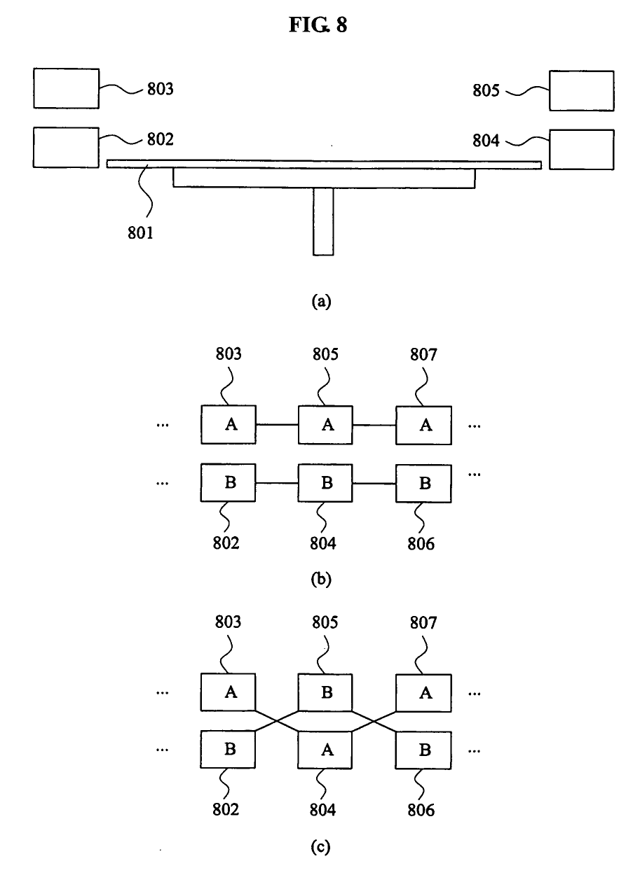

FIG. 8, parts a-c, are views for explaining a configuration of including magnets formed of a plurality of layers in a magnetic field generator and controlling the strength of the magnetic field in the vertical direction in accordance with an embodiment of the present invention.

At the initial stage of forming the liquid photoresist film on the wafer, it is preferable to control the vaporization of the solvent of a liquid photoresist film to make the liquid photoresist film evenly form on a wafer. On the other hand, at the later stage of forming the liquid photoresist film on the wafer, it is preferable to foster the vaporization of the solvent of the liquid photoresist film to enable the liquid photoresist film to be fast formed on the wafer. FIG. 8 is a view for explaining a configuration for achieving the above objective.

A magnetic field generator according to an embodiment of the present invention includes magnets 802, 803, 804, and 805 disposed in two or more layers around the circumference of a wafer 801. If six magnets are disposed around the circumference of the wafer for one layer and two layers are provided, a total of 12 magnets are provided as the magnetic field generator.

In part (a) of FIG. 8, magnets are disposed in two layers. Two magnets 802 and 804 positioned in a first layer and two magnets 803 and 805 positioned in a second layer are illustrated in FIG. 8, but more magnets may be used.

At the initial stage of forming a liquid photoresist film on a wafer, a magnetic field generator having magnets disposed in two layers around the wafer as above controls the magnets so that the density of the lower portion of a solvent vapor layer formed on the wafer is richer that at the upper portion of the solvent vapor layer. This may be performed by making the strength of the magnetic field of the magnets disposed in the lower layer stronger than the magnets disposed in the upper layer at the initial stage of forming the liquid photoresist film on the wafer. For example, it is to make the strength of the magnets 802 and 804 disposed in the lower layer stronger than the magnets 803 and 805 disposed in the upper layer in the initial stage of forming the liquid photoresist film on the wafer. The strength of the magnetic field of the magnets 802, 803, 804, and 805 may be adjusted by, in the case of the electromagnet, controlling an electric current and by, in the case of the permanent magnet, adjusting the horizontal distance between the permanent magnet and the wafer.

Also, at the later stage of forming a liquid photoresist film on a wafer, a magnetic field generator having magnets disposed in two layers around the wafer in accord with an embodiment of the present invention controls the magnets so that the density of the upper portion of a solvent vapor layer formed on the wafer is richer than at the lower portion of the solvent vapor layer. This may be performed by making the strength of the magnetic field of magnets disposed in the upper layer stronger than the magnets in the lower layer at the later stage of forming the liquid photoresist film on the wafer. For example, it is to make the strength of the magnets 802 and 804 disposed in the lower layer lower than the magnets 803 and 805 disposed in the upper layer at the later stage of forming the liquid photoresist film on the wafer.

According to the present embodiment constructed as above, a liquid photoresist film is evenly formed on a wafer by controlling the vaporization of the solvent of the liquid photoresist film at the initial stage of forming the liquid photoresist film on the wafer. Also, the present embodiment enables the solvent of the liquid photoresist film to vaporize easily at the later stage of forming the liquid photoresist film on the wafer, thereby helping the liquid photoresist film to be fast formed on the wafer.

There are grouping control and non-grouping control as a method for controlling the strength of the magnetic field of magnets disposed in two and more layers as above.

The grouping control will be described with reference to part (b) of FIG. 8. In part (b) of FIG. 8, electromagnets are disposed in two and more layers around the circumference of a wafer. In this instance, electromagnets 802, 804, and 806 positioned in a first layer are grouped as one group (B) and electromagnets 803, 805, and 807 are also grouped as the other group (A). After this, the electromagnets grouped as the same group are controlled to have the equivalent strength of the magnetic field. For this, the magnetic field generator includes an electromagnet controller (not illustrated) grouping electromagnets for each layer and controlling the strength of the magnetic field. The electromagnet controller controls the strength of the magnetic field for each layer after grouping magnets comprising the magnetic field generator for said each layer. For example, at the initial stage of forming a liquid photoresist film on a wafer, the electromagnet controller controls the strength of the electromagnets 802, 804, and 806 of a first layer to be stronger than the electromagnets 803, 805, and 807 of a second layer. This may be performed by grouping the electromagnets for each layer and supplying a higher electrical current to the electromagnets of the first layer. Also, as shown in part (c) of FIG. 8, it is possible to control the strength of the magnetic field by grouping the electromagnets disposed around the circumference of the wafer to be crossed with each other.

As another method, there is non-grouping control. In this instance, a magnetic field generator includes an electromagnet controller (not illustrated) individually controlling the at least two electromagnets disposed in the two or more layers around the circumference of a wafer and the strength of the magnetic field of said at least two electromagnets. That is, this is to individually control the electromagnets comprising the magnetic field generator without grouping.

According to the present embodiment constructed as above, it is possible to control the strength of the magnetic field formed around a wafer in the vertical direction. Also, it is possible to control the vertical density of a solvent vapor layer formed on the wafer by independently controlling magnets disposed in two or more layers. Also, it is possible to control the height of the solvent vapor layer formed on the wafer.

FIG. 9 is a top view for explaining a position controller horizontally moving a magnet included in a magnetic field generator, in order to control the strength of the magnetic field of the horizontal direction in accordance with an embodiment of the present invention.

The magnetic field generator of the present embodiment includes a configuration of controlling the strength of the magnetic field of the horizontal direction. As illustrated in parts (a) and (b) of FIG. 7, the magnetic field generator according to an embodiment is provided around the circumference of a wafer. When the magnetic field generator is disposed around the edge of the wafer, the density of a solvent vapor layer formed on the wafer is richer at the edge of the wafer than towards the center thereof. Also, in the case of using a configuration of controlling the strength of the magnetic field of the horizontal direction according to the present invention, it is possible to control the density of the solvent vapor layer in the horizontal direction.

A magnetic field generator as illustrated in FIG. 9 includes six pieces of permanent magnets 901. Also, the magnetic field generator includes a position controller (not illustrated) horizontally moving the magnetic field generator from the center of a wafer. As noted above, in the case permanent magnets are used in the magnetic field generator, the strength of the magnetic field in the horizontal direction may be controlled by horizontally moving the permanent magnets from the center of the wafer, as illustrated in FIG. 9. Also, in the case the strength of the magnetic field in the horizontal direction is controlled, the horizontal density of a solvent vapor layer formed on the wafer is also controlled.

When electromagnets are used in the magnetic field generator, an electromagnet controller (not illustrated) controlling the electromagnets to adjust the strength of the magnetic field may be included. The electromagnet controller may control the strength of the magnetic field generated by the electromagnets by controlling the strength of an electric current supplied to the electromagnets. The electromagnets may be disposed around the circumference of a wafer.

FIG. 10 is a side view for explaining a position controller vertically moving a wafer in accordance with an embodiment of the present invention.

To control a vertical position of a solvent vapor layer formed on a wafer, the photoresist coating apparatus of the present embodiment may further include a position controller (not shown) vertically moving a magnetic field generator provided around the wafer on the basis of a horizontal plane of the wafer. The position controller is to control the vertical direction of a solvent vapor layer, such as the height of the solvent vapor layer formed on the wafer. The position controller vertically moves magnets 1002 provided around a wafer 1001.

According to another embodiment of the present invention, the position controller vertically moves a wafer, not a magnetic field generator, to control the vertical position of the magnetic field generator and the wafer. That is, the position controller controls the vertical location of the magnetic field by vertically moving the wafer. For example, the position controller may control the vertical height of a device by raising or lowering support 1003.

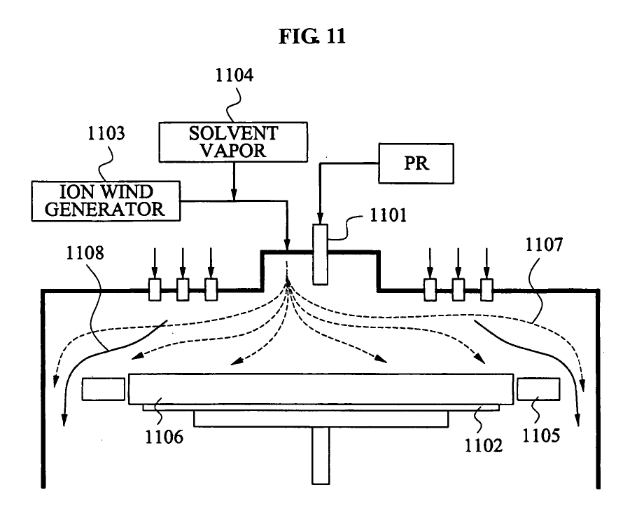

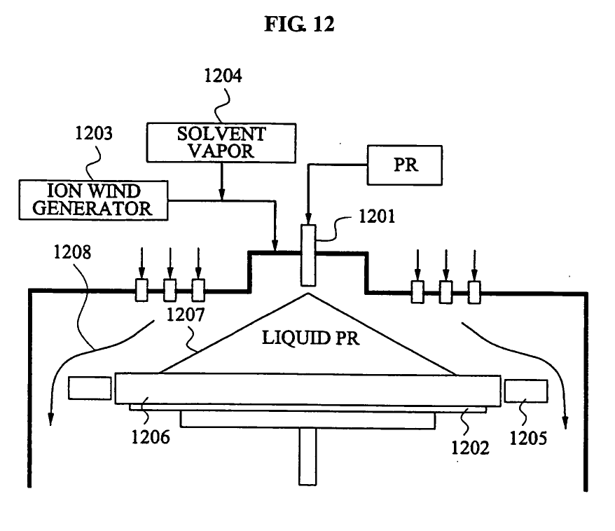

FIGS. 11 and 12 are views explaining a process of coating with photoresist in a spray method according to an embodiment of the present invention.

Referring to FIGS. 11 and 12, solvent vapor 1104 or 1204 is ionized by the ion wind generated by an ion wind generator 1103 or 1203. Ionized solvent vapor 1107 or 1207 is supplied on a wafer 1102 or 1202 and maintained thereon by a magnetic field generator 1105 or 1205. A layer of the ionized solvent vapor formed on the wafer as above is a solvent vapor layer 1106 or 1206. The magnetic field generator 1105 or 1205 is disposed around the circumference of the wafer 1102 or 1202. According to another embodiment of the present invention, a magnetic field generator may be provided in another position without departing from the scope of the present invention.

After a solvent vapor layer is formed on a wafer, a PR spray nozzle 1101 or 1201 sprays a liquid photoresist on the wafer. The liquid photoresist is sprayed on the wafer under the protection of the solvent vapor layer. Thus, it is possible to prevent the solvent of the liquid photoresist from vaporizing while being sprayed and the photoresist from dropping on the wafer in solid particles. Also, according to the conventional art, a part of the sprayed liquid photoresist rides the down flow 1208 and is lost. However, according to the present invention, since the sprayed liquid photoresist is protected from the down flow 1208 by the solvent vapor layer 1206, an amount of the liquid photoresist to be lost is greatly reduced.

At the initial stage of spraying a liquid photoresist, it is preferable to maintain a solvent vapor layer to not vaporize, so that the solvent vapor layer protects the sprayed liquid photoresist. Thus, in the present invention, at the initial stage of spraying the liquid photoresist, the magnetic field generator is controlled to make the density of the lower portion of the solvent vapor layer formed on the wafer richer than at the upper portion of the solvent vapor layer.

Also, according to an embodiment of the present invention, the height of a spray nozzle spraying a liquid photoresist from the surface of a wafer is substantially same to the height of a solvent vapor layer. This is to make the liquid photoresist reach the surface of the wafer under protection of the solvent vapor layer, just right after the liquid photoresist has been sprayed. Also, solvent vapor has to vaporize or be completely removed in the end for photoresist coating. Thus, if the solvent vapor layer is too thick, more solvent vapor is spent. Accordingly, it is preferable that the height of the solvent vapor layer is substantially same to the height of the spray nozzle spraying a liquid photoresist from the surface of a wafer. The height of the spray nozzle has to be selected so that the liquid photoresist may be evenly sprayed over the entire wafer. Thus, the height of a solvent vapor layer formed on the wafer is controlled by using a magnetic field generator. Just, in this instance, the height of the solvent vapor layer may be embodied to be lower than the height of the spray nozzle by considering the cost.

A liquid photoresist is coated on a wafer by spraying the liquid photoresist on the wafer and vaporizing the solvent of the liquid photoresist. As above, the solvent of the liquid photoresist has to be vaporized after spraying the liquid photoresist. In order to foster the vaporization of the solvent of the liquid photoresist, it is preferable that the density of the upper portion of a solvent vapor layer is richer than the density of the lower portion thereof to enable the solvent vapor layer surrounding the liquid photoresist to quickly vaporize. Accordingly, in the present invention, the magnetic field generator is controlled so that the density of the upper portion of the solvent vapor layer formed on the wafer is richer than the density than the lower portion of the solvent vapor layer at the later stage of spraying the liquid photoresist on the wafer.

FIG. 13 is a view for explaining how an edge bead problem is solved in accordance with an embodiment of the present invention.

Since the superficial area of a liquid photoresist film formed on a wafer is wider at the edge of the wafer than towards the center thereof, the solvent of the liquid photoresist film vaporizes more at the edge of the wafer. This is because the liquid photoresist film formed at the edge of the wafer has the wider superficial area making contact with the air. Since the solvent vaporizes more at the edge of the wafer than towards the center thereof as described above, the density of the liquid photoresist is richer at the edge of the wafer than towards the center thereof. When the density of the liquid photoresist gets richer, its surface tension also increases. Accordingly, an edge bead problem that an edge protrudes after the solvent vaporizes occurs. The edge bead problem occurs not only in photoresist coating of a spray method but also in photoresist coating of a spin method.

As illustrated in FIG. 13, in the present embodiment, since a solvent vapor layer 1303 surrounds a liquid photoresist film formed on a wafer 1301, the solvent of the liquid photoresist film does not vaporize. Accordingly, since the density of the liquid photoresist film 1302 formed on the wafer 1301 is certain from the center of the wafer to the edge thereof, the edge bead problem does not occur.

The liquid photoresist film 1302 and the solvent vapor layer 1303 stick together. Thus, it is preferable that the solvent of the liquid photoresist film 1302 and the solvent of the solvent vapor are the same type of solvent. However, although they are not the same type of solvent, in the case of a solvent having the characteristic of protecting a liquid photoresist film and easily vaporizing after the liquid photoresist film is formed on a wafer, the solvent may be used as the solvent of the solvent vapor. In an embodiment of the present invention, a polymethylmethacrylate (PMMA) is employed as the solvent of the solvent vapor.

Also, in an embodiment of the present invention, a magnetic field generator is provided around a wafer. Thus, the density of a solvent vapor layer is richer at the edge of the wafer than towards the center thereof. It has been described with reference to part (b) of FIG. 7. Since the superficial area of a solvent vapor layer according to the present invention is also wider at the edge of the wafer than towards the center thereof, the solvent vapor vaporizes more at the edge of the wafer. However, the magnetic field generator according to an embodiment of the present invention is controlled to make the density of the solvent vapor layer at the edge of the wafer richer than that towards the center thereof. In other words, an amount of the solvent vapor is more at the edge of the wafer than towards the center thereof. Thus, although the solvent vapor vaporizes more at the edge of the wafer, a certain amount of the solvent vapor overall surrounds the liquid photoresist film.

According to an embodiment of the present invention, the strength of the magnetic field of the magnetic field generator is selected so that the density of the solvent vapor layer disposed at the edge of the wafer is richer than the density of the solvent vapor layer disposed towards the center of the wafer, in the solvent vapor layer formed on the wafer.

According to another embodiment of the present invention, the strength of the magnetic field of the magnetic field generator is selected to make a uniform photoresist film formed on the wafer after the solvent of the solvent vapor and the liquid photoresist vaporizes.

According to the above-described embodiments of the present invention, the density of the liquid photoresist film 1302 formed on the wafer 1301 is equivalent both towards the center of the wafer 1301 and at the edge thereof. Thus, an edge bead problem occurring because the density of a liquid photoresist is richer at the edge of the wafer does not occur. Consequently, a photoresist film 1305 coated on a wafer 1304 after the solvent of the solvent vapor layer 1303 and the liquid photoresist film 1302 vaporizes out is evenly formed through the center of the wafer 1304 to the edge thereof.

According to the test of an inventor of the present invention, when the strength of the magnetic field of the magnetic field generator is between 0.05 T and 0.15 T, an edge bead did not occur. In this instance, the strength of the magnetic field may have been selected as an optimum value in accord with each embodiment of the present invention.

FIG. 14 is a view explaining a process of coating photoresist in a spin method in accordance with an embodiment of the present invention.

Solvent vapor 1404 is ionized by the ion wind generated by an ion wind generator 1403. Ionized solvent vapor 1407 is supplied on a wafer 1402 and maintained thereon by a magnetic field generator 1405. As above, a solvent vapor layer 1406 is formed on the wafer 1402 by the magnetic field generator 1405. The magnetic field generator 1405 is disposed around the circumference of the wafer 1402. According to another embodiment of the present invention, a magnetic field generator may be provided in another position without departing from the scope of the present invention.

After forming a solvent vapor layer on a wafer, a liquid photoresist is dropped on the wafer from a PR nozzle 1401. It is preferable to maintain the solvent vapor layer to not vaporize, in order to enable the solvent vapor layer to protect the dropped liquid photoresist at the initial stage of dropping the liquid photoresist. Accordingly, in the present invention, the magnetic field generator is controlled so that the density of the lower portion of the solvent vapor layer formed on the wafer is richer than the density of the upper portion of the solvent vapor layer at the initial stage of dropping the liquid photoresist.

Also, according to an embodiment of the present invention, the height 1410 of the PR nozzle 1401 dropping a liquid photoresist from the surface of a wafer is substantially the same as the height 1411 of the solvent vapor layer 1406. This is to make a liquid photoresist reach the surface of the wafer under protection of the solvent vapor layer right after the liquid photoresist is dropped from the PR nozzle 1401.

Next, a revolution axle 1409 rotates the wafer 1402 and through this, the liquid photoresist dropped on the wafer 1402 is evenly spread over the entire surface of the wafer 1402. The down flow 1408 makes the liquid photoresist splatter to the outside of the wafer 1402 because of the rotation of the revolution axle 1409 drop to the floor, not on the wafer 1402 again.

After a liquid photoresist is spread evenly over the entire surface of a wafer, photoresist is coated on the wafer by vaporizing the solvent of the liquid photoresist. As described above, the solvent of the liquid photoresist has to be vaporized at the later stage of forming a liquid photoresist film on the wafer. Accordingly, to foster the vaporization of the solvent of the liquid photoresist, it is preferable that the density of the upper portion of a solvent vapor layer is richer than at the lower portion of the solvent vapor layer to enable the solvent vapor layer surrounding the liquid photoresist to quickly vaporize.

According to the above-described embodiments of the present invention, a photoresist coating apparatus and method can coat photoresist evenly on a wafer without forming a bead on the edge of the wafer, in photoresist coating.

According to the above-described embodiments of the present invention, a photoresist coating apparatus and method can reduce an amount of liquid photoresist lost which rides the down flow and drops on the floor in photoresist coating.

Also, according to the above-described embodiments of the present invention, it is possible to reduce an amount of photoresist dropping on a wafer as solid particles as a liquid photoresist vaporizes, when the photoresist is coated on the wafer in a spray method.

Also, according to the above-described embodiments of the present invention, it is possible to control the vaporization of the solvent of a liquid photoresist film at the initial stage of forming the liquid photoresist film on a wafer, and enable the liquid photoresist film to be evenly formed on the wafer.

Also, according to the above-described embodiments of the present invention, it is possible to foster the vaporization of the solvent of a liquid photoresist film at the later stage of forming the liquid photoresist film on a wafer, and enable the liquid photoresist film to be quickly formed on the wafer and reduce time spent in the photoresist process.

Also, according to the above-described embodiments of the present invention, there is provided a photoresist coating apparatus and method which can adjust the vertical and horizontal density of a solvent vapor layer formed on a wafer.

Also, according to the above-described embodiments of the present invention, there is provided a photoresist coating apparatus and method which can protect a liquid photoresist while reducing an amount of solvent vapor supplied to protect the liquid photoresist.

Embodiments of the present invention have mainly described a photoresist coating apparatus and method, but the present invention is applicable not only to coating of photoresist but also to coating of other materials, without departing from the scope of the present invention.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

What is claimed is:

1. A photoresist coating apparatus comprising:
a solvent ionizer supplying ionized solvent vapor; and
a magnetic field generator forming a solvent vapor layer on a wafer from the ionized solvent vapor.

2. The photoresist coating apparatus of claim 1, wherein the solvent ionizer ionizes solvent vapor by using an ion wind, thereby generating the ionized solvent vapor.

3. The photoresist coating apparatus of claim 2, wherein the solvent ionizer comprises:
an ion wind generator generating the ion wind; and
a piezoelectric device vaporizing a solvent, thereby generating the solvent vapor.

4. The photoresist coating apparatus of claim 3, wherein the ion wind generator comprises:
a corona discharger generating a corona discharge, thereby generating negative ions; and
an insulating conductor guiding the negative ions to the position where the solvent vapor is formed.

5. The photoresist coating apparatus of claim 1, wherein the solvent of the solvent vapor and the solvent of the liquid photoresist are same type of solvent.

6. The photoresist coating apparatus of claim 1, wherein the solvent of the solvent vapor is polymethylmethacrylate (PMMA).

7. The photoresist coating apparatus of claim 1, wherein the magnetic field generator is disposed around a circumference of the wafer.

8. The photoresist coating apparatus of claim 7, further comprising a position controller moving the magnetic field generator horizontally from a center of the wafer.

9. The photoresist coating apparatus of claim 8, wherein the magnetic field generator is at least one permanent magnet disposed around the circumference of the wafer.

10. The photoresist coating apparatus of claim 7, wherein the magnetic field generator comprises:
at least one electromagnet disposed around the circumference of the wafer; and
an electromagnet controller controlling adjusting a strength of a magnetic field of the at least one electromagnet.

11. The photoresist coating apparatus of claim 7, further comprising a position controller moving the magnetic field generator vertically with respect to the horizontal plane of the wafer.

12. The photoresist coating apparatus of claim 7, further comprising a position controller moving the wafer vertically.

13. The photoresist coating apparatus of claim 7, wherein the magnetic field generator includes at least two magnets disposed in two or more layers around the circumference of the wafer.

14. The photoresist coating apparatus of claim 13, wherein the magnets are controlled so that a density of a lower portion of a solvent vapor layer formed on the wafer is richer than a density of an upper portion of the solvent vapor layer at an initial stage of forming a liquid photoresist film on the wafer.

15. The photoresist coating apparatus of claim 14, wherein a strength of the magnetic field of the magnet disposed on a lower layer is controlled to be stronger than a strength of the magnet disposed on an upper layer at an initial stage of forming a liquid photoresist film on the wafer.

16. The photoresist coating apparatus of claim 13, wherein the magnets are controlled so that a density of an upper portion of a solvent vapor layer formed on the wafer is richer than a density of a lower portion of the solvent vapor layer at a later stage of forming a liquid photoresist film on the wafer.

17. The photoresist coating apparatus of claim 16, wherein the strength of the magnetic field of the magnet disposed on an upper layer is controlled to be stronger than the strength of the magnet disposed on a lower layer at the later stage of forming a liquid photoresist film on the wafer.

18. The photoresist coating apparatus of claim 7, wherein the magnetic field generator comprises:
at least two electromagnets disposed in two or more layers around the circumference of the wafer; and
an electromagnet controller grouping the at least two electromagnets for each layer to adjust a strength of the magnetic field.

19. The photoresist coating apparatus of claim 7, wherein the magnetic field generator comprises:
at least two electromagnets disposed in two or more layers around the circumference of the wafer; and
an electromagnet controller individually controlling a strength of each magnetic field of the at least two magnets.

20. The photoresist coating apparatus of claim 1, wherein a strength of a magnetic field of the magnetic field generator is selected so that a density of the solvent vapor layer positioned at an edge of the wafer is richer than a density of the solvent vapor layer positioned towards a center of the wafer, in the solvent vapor layer formed on the wafer.

21. The photoresist coating apparatus of claim 1, wherein a strength of a magnetic field of the magnetic field generator is selected to make a uniform photoresist film formed on the wafer after the solvent of the solvent vapor and the liquid photoresist vaporizes.

22. The photoresist coating apparatus of claim 1, wherein a strength of a magnetic field of the magnetic field generator is between 0.05 T and 0.15 T.

23. The photoresist coating apparatus of claim 1, further comprising a spray nozzle spraying a liquid photoresist on the wafer.

24. The photoresist coating apparatus of claim 23, wherein a height of the spray nozzle from a surface of the wafer is substantially equal to a height of the solvent vapor layer formed by the magnetic field generator.

25. A coating apparatus comprising:
a solvent ionizer supplying ionized solvent vapor; and
a magnetic field generator forming a solvent vapor layer by the ionized solvent vapor on a wafer.

26. The coating apparatus of claim 25, wherein the magnetic field generator is disposed around a circumference of the wafer.

27. The coating apparatus of claim 26, wherein the magnetic field generator is controlled so that a density of a lower portion of a solvent vapor layer formed on the wafer is richer than a density of an upper portion of the solvent vapor layer at an initial stage of forming a liquid coating on the wafer.

28. The coating apparatus of claim 26, wherein the magnetic field generator is controlled so that a density at an upper portion of a solvent vapor layer formed on the wafer is richer that a density at a lower portion of the solvent vapor layer at a later stage of forming a liquid coating on the wafer.

29. The coating apparatus of claim 26, wherein a strength of the magnetic field of the magnetic field generator is selected so that a density of the solvent vapor layer disposed at an edge of the wafer is richer than a density of the solvent vapor layer disposed towards a center of the wafer, in the solvent vapor layer formed on the wafer.

30. A photoresist coating method comprising:
forming a solvent vapor layer on a wafer from ionized solvent vapor by using a magnetic field generator;
dropping a liquid photoresist on the wafer and rotating the wafer; and
vaporizing the solvent of the liquid photoresist.

31. The photoresist coating method of claim 30, further comprising:
ionizing solvent vapor by using an ion wind, thereby generating the ionized solvent vapor.

32. The photoresist coating method of claim 30, wherein the magnetic field generator is disposed around a circumference of the wafer.

33. A photoresist coating method comprising:
forming a solvent vapor layer of ionized solvent vapor on a wafer by using a magnetic field generator;
spraying a liquid photoresist on the wafer; and
vaporizing the solvent of the liquid photoresist.

34. The photoresist coating method of claim 33, wherein a height of a spray nozzle spraying the liquid photoresist from a surface of the wafer is substantially equal to a height of the solvent vapor layer.

35. The photoresist coating method of claim 33, wherein the magnetic field generator is disposed around a circumference of the wafer.

36. The photoresist coating method of claim 33, wherein the magnetic field generator is controlled so that a density of a lower portion of a solvent vapor layer formed on the wafer is richer than a density of an upper portion of the solvent vapor layer at an initial stage of spraying the liquid photoresist.

37. The photoresist coating method of claim 34, wherein the magnetic field generator is controlled so that a density of an upper portion of a solvent vapor layer formed on the wafer is richer than a density of a lower portion of the solvent vapor layer at a later stage of spaying the liquid photoresist.
